(19) United States
(12) Patent Application Publication
(10) Pub. No.: US 2023/0178330 A1
(43) Pub. Date: Jun. 8, 2023

(54) Method for Controlling Position of Sample in Charged Particle Beam Device, Program, Storage Medium, Control Device, and Charged Particle Beam Device

(71) Applicant: Hitachi High-Tech Corporation, Minato-ku, Tokyo (JP)

(72) Inventor: Kazuki ISHIZAWA, Tokyo (JP)

(21) Appl. No.: 17/923,944

(22) PCT Filed: May 29, 2020
(86) PCT No.: PCT/JP2020/021395

§ 371 Date: Nov. 8, 2022

(51) Int. Cl. H01J 37/20

(52) U.S. Cl. CPC H01J 37/20; H01J 2237/20264

(57) ABSTRACT

A scanning/transmission electron microscope 1 moves a sample 59 using an X-piezoelectric element 54, a Y-piezoelectric element 55, and a Z-piezoelectric element 65. A method for controlling the position of the sample 59 includes a first movement step of moving the sample 59 toward a target position, a second movement step of moving the sample 59 away from the target position, after the first movement step, and a third movement step of moving the sample 59 toward the target position, after the second movement step.

### TECHNICAL FIELD

The present invention relates to a method for controlling a position of a sample in a charged particle beam device, a program, a storage medium, a control device, and the charged particle beam device, and particularly to those using a piezoelectric element.

### BACKGROUND ART

In the related art, in a charged particle beam device, a motor (stepping motor, servomotor, ultrasonic motor, and the like) or a linear actuator is used as a position control mechanism of a stage.

Especially in a high-resolution charged particle beam microscope, a high-resolution position control mechanism may be required. In that case, a stage position control mechanism is configured by using the piezoelectric element to realize high-resolution position control.

Meanwhile, a creep phenomenon occurs in the piezoelectric element. The creep phenomenon is a phenomenon in which displacement continues to change smoothly after a commanded displacement is achieved. Since this phenomenon causes stage position drift, it is common to perform feedback control using a position detection element.

### CITATION LIST

### Patent Literature

PTL 1: JP-A-53-031990

### SUMMARY OF INVENTION

### Technical Problem

However, especially in the stage of the high-resolution type charged particle beam microscope, there was a problem that it was difficult to realize a positional displacement of the sample with high accuracy.

For example, although accuracy can be improved by feedback control using the position detection element, it may be structurally difficult to arrange the position detection element near the sample. Further, when the position detection element is arranged near the sample using an additional mechanism and the like, expansion and contraction of the additional mechanism due to temperature change may cause a position drift phenomenon of the stage and erroneous detection of the position.

Therefore, the present invention has been made in view of such problems, and an object of the present invention is to provide a method, a program, a storage medium, a control device, and a charged particle beam device for realizing the positional displacement of the sample with high accuracy.

### Solution to Problem

An example of a method according to the present invention is a method for controlling a position of a sample in a charged particle beam device that moves the sample using a piezoelectric element, the method comprising a first movement step of moving the sample toward a target position, a second movement step of moving the sample away from the target position after the first movement step, and a third movement step of moving the sample toward the target position after the second movement step.

An example of a program according to the present invention causes the charged particle beam device to perform the method described above.

An example of a storage medium according to the present invention stores the program described above.

An example of a control device according to the present invention is a control device of the charged particle beam device, which executes the method described above.

An example of the charged particle beam device according to the present invention includes a sample holder on which a sample is placed, a piezoelectric element that is connected to the sample holder and moves the sample, and the control device described above.

### Advantageous Effects of Invention

The method, program, storage medium, control device, and charged particle beam device according to the present invention can realize the positional displacement of the sample with high accuracy.

For example, the creep displacement of stage motion using the piezoelectric element can be reduced without using a sensor. Further, it is possible to avoid deterioration of positional accuracy due to deformation of the structure itself for attaching the sensor.

In JP-A-53-031990 (PTL 1), in order to suppress the creep phenomenon of the piezoelectric element, an overvoltage exceeding a drive voltage corresponding to a target deformation amount of the piezoelectric element is applied for a certain period of time, and then the voltage is continuously reduced to the drive voltage corresponding to the target deformation amount without cutting off the voltage. However, since the maximum/minimum applied voltage is prescribed for the piezoelectric element, when the piezoelectric element is deformed to near the maximum/minimum voltages, a voltage exceeding the drive voltage cannot be applied, and the creep phenomenon cannot be suppressed. According to the present invention, even when the piezoelectric element is deformed to near the maximum/minimum voltage, the positional displacement of the sample can be realized with high accuracy.

### BRIEF DESCRIPTION OF DRAWINGS

FIG. 1 is a configuration diagram illustrating a schematic configuration example of a scanning/transmission electron microscope according to a first example of the present invention.

FIG. 2 is a diagram illustrating details around a stage of FIG. 1.

FIG. 3 is a diagram illustrating the portion illustrated in FIG. 2 from a horizontal direction.

FIG. 4 is a graph illustrating a method of controlling a piezoelectric element according to the first example.

FIG. 5 is a diagram illustrating a typical example of a creep phenomenon.

FIG. 6 is a diagram illustrating an algorithm for calculating a creep displacement of the piezoelectric element.

FIG. 7 is a diagram illustrating an algorithm for calculating a correction value used for a correcting operation.

FIG. 8 is a diagram illustrating an algorithm for performing correction using a correction value obtained by the process of FIG. 7.

FIG. 9 is a diagram illustrating an algorithm for calculating a correction value used for a correcting operation.

FIG. 10 is a diagram illustrating an algorithm for correction using the correction value obtained by the process of FIG. 9.

FIG. 11 is a diagram illustrating an example of a user interface.

FIG. 12 is a diagram illustrating another example of the user interface.

FIG. 13 is a diagram illustrating another example of the user interface.

FIG. 14 is a diagram illustrating another example of the user interface.

FIG. 15 is a diagram illustrating another example of the user interface.

### DESCRIPTION OF EMBODIMENTS

Hereinafter, a charged particle beam device of an embodiment of the present invention will be described based on the drawings. The present invention relates to a method for controlling a position of a sample in the charged particle beam device, a program, a storage medium, a control device, and the charged particle beam device.

In the description, as the charged particle beam device, a scanning/transmission electron microscope in which the stage is entered from the side will be described as an example, but the charged particle beam device according to the present invention is not limited to the scanning/transmission electron microscope, nor is it limited to one in which the stage is entered from the side.

In the charged particle beam device according to the present invention, a sample is placed on a sample holder (or other pedestal similar to the sample holder). The sample holder is moved by an actuator using a piezoelectric element. With this configuration, an irradiation position of a charged particle beam with respect to the sample (or pedestal) can be changed. The charged particle beam device includes, for example, a scanning ion microscope and a scanning electron microscope. Further, the charged particle beam device may be a composite device of these microscopes and a sample processing device. Further, the charged particle beam device includes an analysis device and inspection device to which these microscopes are applied.

### First Example

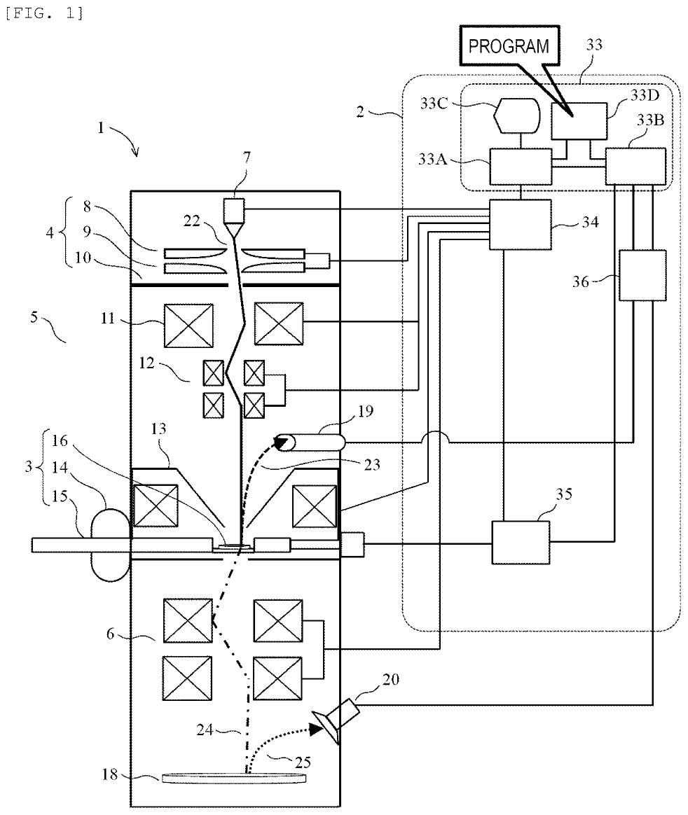

FIG. 1 is a configuration diagram illustrating a schematic configuration example of a scanning/transmission electron microscope 1, as a charged particle beam device according to a first example of the present invention.

The scanning/transmission electron microscope 1 includes an electron gun 4, an electron optical system 5, an imaging system 6, and a stage 3 for moving the sample, and is configured by integrating these components. A vacuum is maintained in a lens barrel of the scanning/transmission electron microscope 1 by means of vacuum evacuation means (not illustrated).

The scanning/transmission electron microscope 1 includes a control device 2. The control device 2 controls the scanning/transmission electron microscope 1 by controlling each component of the scanning/transmission electron microscope 1. The control device 2 can execute the method described in this specification.

Primary electrons 22 are emitted from an electron source 7. The primary electrons 22 are focused and accelerated by using a suppression electrode 8, an extraction electrode 9 and an anode 10 within the electron gun 4. After that, the primary electrons 22 are enlarged or reduced and deflected by a focusing lens 11, deflection lens 12 and objective lens 13 in the electron optical system 5. After that, the sample placed on a sample holder 16 at the tip of a stage rod 15 is irradiated with the primary electrons 22.

Signal electrons 23 are generated from the sample irradiated with electrons by reflection and secondary electron emission. The signal electrons 23 are detected by a detector 19. A signal from the detector 19 is processed by a signal processing unit 36, processed by an image processing unit 33B in a computer 33, processed by a CPU 33A, and displayed by a display device 33C.

Among the electrons with which the sample is irradiated, electrons that have passed through the sample (transmitted electrons 24) are reduced or enlarged by the imaging system 6 and a fluorescent plate 18 is irradiated therewith. When irradiated with the transmitted electrons 24, fluorescence 25 is generated from the fluorescent plate 18. The generated fluorescence 25 is detected by a camera 20. A signal from the camera 20 is processed by the signal processing unit 36, processed by the image processing unit 33B in the computer 33, processed by the CPU 33A, and displayed on the display device 33C.

In addition to the matters described above, the scanning/transmission electron microscope 1 may include detectors such as a charged particle beam detector, an optical detector, and an X-ray detector (not illustrated), and may be provided with an aperture mechanism and the like related to these detectors.

The stage 3 includes a stage drive mechanism 14, the stage rod 15, and the sample holder 16. The sample holder 16 is connected to the tip of the stage rod 15. The sample is placed on the sample holder 16. A position of a field of view is changed by driving the stage 3. When the position of the field of view is adjusted, the stage drive mechanism 14 operates according to a command from a stage control unit 35 to realize motions such as pushing, pulling, rotating, sending, and the like with respect to the stage rod 15. These motions may be realized through atmospheric pressure or spring force, or by canceling pre-applied atmospheric pressure or spring force.

The control device 2 includes the computer 33, a main control unit 34, the stage control unit 35, and the signal processing unit 36, and controls each component of the scanning/transmission electron microscope 1.

An instruction related to movement, rotation, tilt, and the like of the stage 3 is provided to the stage control unit 35 from the main control unit 34. The stage control unit 35 drives and controls the stage drive mechanism 14 according to this command. Further, the image processing unit 33B in the computer 33 provides information on movement, rotation, tilt, and the like of an image to the stage control unit 35. The stage control unit 35 computes a necessary correcting operation based on these pieces of information, and corrects the drive control of the stage drive mechanism 14.

The computer 33 can be configured by a computer having a known configuration. For example, the computer 33 includes computing means for performing computation, storage means for storing information, and input and output means for inputting and outputting information. The storage means includes, for example, non-transitory storage media. The storage means can store the program. The computer 33 realizes the operations described in this specification by executing this program by the computing means. Accordingly, the scanning/transmission electron microscope 1 realizes the operations described in this specification. That is, the program causes the scanning/transmission electron microscope 1 to execute the method described in this specification.

In this example, the computing means includes the CPU 33A and the image processing unit 33B, the input and output means includes the display device 33C, and the storage means includes a memory 33D as a storage medium. The computer 33 can perform computations related to signals, and transmission and reception of information (commands, and the like) with respect to each device. Further, the computer 33 also serves as an interface with people and other electronic devices.

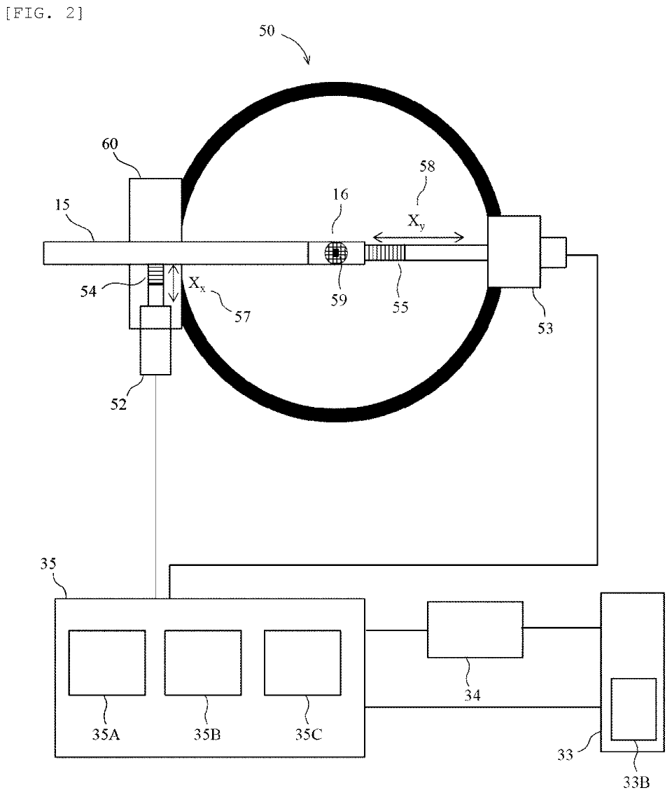

FIG. 2 is a diagram illustrating details around the stage 3 of FIG. 1. Details of the stage motion will be described with reference to FIG. 2.

An X-actuator 52, a Y-actuator 53, and a stage rod insertion mechanism 60 are installed in an electron microscope main body 50. The stage rod 15 is inserted into the electron microscope main body 50 through the stage rod insertion mechanism 60. An X-piezoelectric element 54 is attached to the tip of the X-actuator 52, and a Y-piezoelectric element 55 is attached to the tip of the Y-actuator 53.

The stage can be moved in a movement direction Xₓ 57 using the X-actuator 52 and the X-piezoelectric element 54, and can be moved in a movement direction X_{y} 58 using the Y-actuator 53 and the Y-piezoelectric element 55.

The sample holder 16 is connected to the tip of the stage rod 15. The sample 59 is placed on the sample holder 16. The sample is an object to be observed. Each piezoelectric element is connected to the sample holder 16, and moves the sample.

Among movements of the stage, the X-actuator 52 and the Y-actuator 53 are used particularly for relatively rough movement (coarse motion), and the expansion and contraction due to a piezoelectric effect of the X-piezoelectric element 54 and the Y-piezoelectric element 55 are used particularly for relatively minute movement (fine motion). The coarse motion and fine motion are realized as motions such as pushing, pulling, turning, and sending with respect to the stage rod 15, for example. These motions may be realized through atmospheric pressure or spring force, may be realized by canceling pre-applied atmospheric pressure or spring force, or may be realized through a lever (not illustrated).

The stage control unit 35 controls each actuator and each piezoelectric element. The stage control unit 35 includes a stage motion computation unit 35A, a motor driver 35B, and a piezoelectric driver 35C.

Each actuator is controlled by the motor driver 35B. Each piezoelectric element is controlled by the piezoelectric driver 35C. The motor driver 35B and piezoelectric driver 35C have the function of receiving a signal representing a commanded deformation amount of the actuator and piezoelectric element from a host unit (the main control unit 34 and image processing unit 33B in this example), converting this signal into a voltage, and outputting the voltage to the actuator and piezoelectric element.

The main control unit 34 receives a signal representing a displacement command or a signal representing designated coordinates from the computer 33 and transmits a signal to stage control unit 35 based on that signal. A decision as to whether to operate each actuator or deform each piezoelectric element for stage movement is made based on the displacement command or designated coordinates. This decision is made by the computer 33, the main control unit 34, or the stage motion computation unit 35A.

As an example of an operation method of the actuator and the piezoelectric element, it is also possible to adopt a configuration in which the movement according to the displacement command or the designated coordinates is performed using only the actuator, and then the backlash of the actuator and the like is decided from the image processing unit 33B, and each piezoelectric element is used only for correction thereof.

As another example of the operation method of the actuator and the piezoelectric element, it is also possible to adopt a configuration in which the movement according to the displacement command or designated coordinates is performed using only the actuator, and then the field of view is adjusted using each piezoelectric element for the purpose of acquiring a wide field of view.

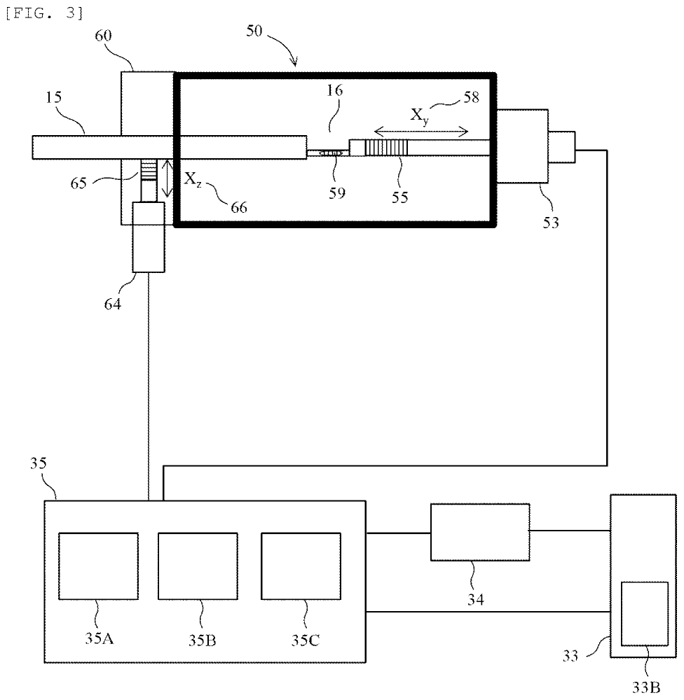

FIG. 3 is a diagram illustrating the portion illustrated in FIG. 2 from a horizontal direction (for example, the X-direction).

FIG. 3 illustrates a Z-actuator 64 and a Z-piezoelectric element 65 for moving the stage in a direction parallel to the direction of the charged particle beam. The stage can be moved in a movement direction X_{z} 66 using the Z-actuator 64 and Z-piezoelectric elements 65.

The scanning/transmission electron microscope 1 may further include a Tilt axis and an Azimuth axis (axis for irradiating the sample with the charged particle beam at an angle with respect to the sample) (not illustrated), and include a Rotation axis for rotating the sample itself.

<Method for Driving Piezoelectric Element According to First Example>

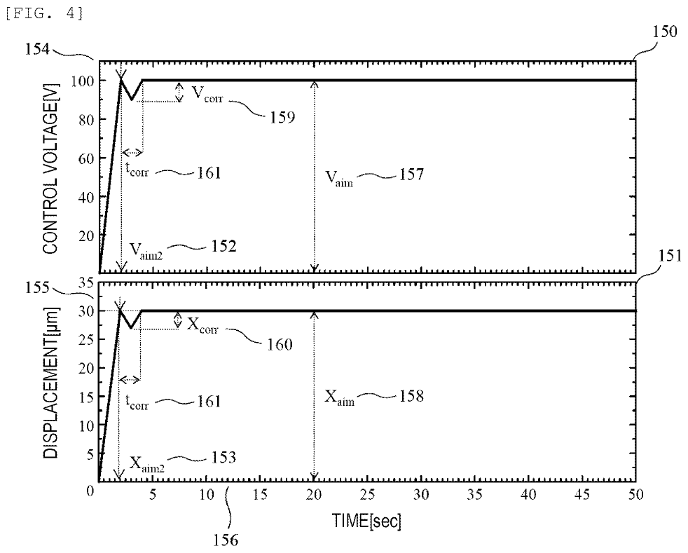

FIG. 4 is a graph illustrating a method of controlling the piezoelectric element according to the first example. A voltage-time graph 150 at the upper part of the FIG. 4 illustrates the relationship between control voltage and time. A displacement-time graph 151 at the lower part of the FIG. 4 illustrates the relationship between displacement distance and time.

FIG. 4 is graph schematically representing an example of a control method in which a piezoelectric element with a full stroke can be used and the creep phenomenon can be suppressed.

The creep phenomenon is a phenomenon peculiar to the piezoelectric element. A typical example of the creep phenomenon is illustrated in FIG. 5. The voltage-time graph 200 at the upper part of the FIG. 5 illustrates the relationship between control voltage and time. The vertical axis of the graph (control voltage axis 202) indicates voltage. The horizontal axis of the graph (time axis 204) indicates elapsed time from a given point. Vₐᵢₘ 205 is a voltage value assumed to correspond to target deformation of the piezoelectric element (that is, the target position of the sample).

The displacement-time graph 201 at the lower part of the FIG. 5 illustrates the relationship between time and displacement. The vertical axis of the graph (displacement axis 203) indicates a displacement amount. The horizontal axis (time axis 204) indicates elapsed time. Xs 206 is the displacement amount corresponding to Vₐᵢₘ 205.

When the voltage-time graph 200 and the displacement-time graph 201 are compared, it can be seen that the displacement amount by the piezoelectric element changes gently even though the voltage is not changed after Vₐᵢₘ 205 is applied. This phenomenon is the creep phenomenon. β1 207 represents creep displacement. Ts2 208 indicates the time from application of Vₐᵢₘ 205 to creep displacement by β1 207. A principle of generation of the creep phenomenon is attributed to the fact that it takes a certain amount of time for a polarization direction of the piezoelectric element to change.

The voltage-time graph 150 in FIG. 4 is a diagram schematically representing the control method according to this example, and particularly represents the relationship between the control voltage and time. A unit of the control voltage axis 154 is voltage [V], which indicates a value of a voltage applied to the piezoelectric element. A unit of the time axis 156 is time [seconds] and counting up is performed by setting any timing as 0 seconds. Here, the moment when the control voltage applied to the piezoelectric element starts to increase from 0[V] is set as 0 [seconds], but it is not necessary to be limited thereto.

Vₐᵢₘ 157 indicates the voltage corresponding to a target deformation amount of the piezoelectric element (that is, the target position of the sample). Vₐᵢₘ₂ 152 is equal to Vₐᵢₘ 157 in this example, but may be less than Vₐᵢₘ 157 as described below. Vₐᵢₘ₂ 152 is applied before Vₐᵢₘ 157.

V_{corr} 159 is a voltage variation for suppressing the creep displacement by the piezoelectric element, and a unit is voltage[V]. The sign of V_{corr} 159 is opposite to Vₐᵢₘ₂ 152 and an absolute value of V_{corr} 159 is smaller than Vₐᵢₘ₂ 152 and Vₐᵢₘ 157. The t_{corr} 161 is the time during which V_{corr} 159 is applied (more precisely, the time from when the voltage starts to decrease from Vₐᵢₘ₂ 152 to when it starts to increase, or the time from when the voltage starts to decrease from Vₐᵢₘ₂ 152 to when it reaches Vₐᵢₘ 157).

The displacement-time graph 151 schematically illustrates the relationship between the displacement by the piezoelectric element and the elapsed time when the voltage illustrated in the voltage-time graph 150 is applied. A unit of the displacement axis 155 is displacement [μm], which expresses the scale of the displacement amount by a realistic piezoelectric element, but the unit may be [mm] or [nm]. Xₐᵢₘ 158 is the displacement when Vₐᵢₘ 157 is applied, and Xₐᵢₘ₂ 153 is the displacement when Vₐᵢₘ₂ 152 is applied.

Xₐᵢₘ 158 corresponds to the target position to which the sample is finally intended to be moved. X_{corr} 160 is a variation in the displacement amount when the applied voltage is decreased by V_{corr} 159. The t_{corr} 161 appears on both the voltage-time graph 150 and the displacement-time graph 151, which represent the same length of time.

The graph of FIG. 4 illustrates the relatively long time required for the change in voltage to follow the command. For example, in the example of FIG. 4, the control voltage increases from 0 to Vₐᵢₘ₂ 152 and begins to decrease at the moment when Vₐᵢₘ₂ 152 is reached. However, the change in voltage may follow the command more quickly, for example, after the control voltage reaches Vₐᵢₘ₂ 152 almost instantaneously, the control voltage may maintain Vₐᵢₘ₂ 152 until a voltage command value decreases, and then decrease by V_{corr} 159 almost instantaneously, and then maintain that value until the voltage command value increases.

This example is characterized by the applied voltage. The relationship of each applied voltage is Vₐᵢₘ 157≥Vₐᵢₘ₂ 152>V_{corr} 159 (Equation 1) in terms of absolute value. Vₐᵢₘ 157 is the voltage corresponding to the target position of the sample, but according to Equation 1, Vₐᵢₘ₂ 152 is always less than or equal to Vₐᵢₘ 157, and thus application of Vₐᵢₘ₂ 152 does not cause the sample to move beyond the target position. Therefore, when the control voltage decreases from Vₐᵢₘ₂ 152 by V_{corr} 159, the sample always moves in a direction away from the target position.

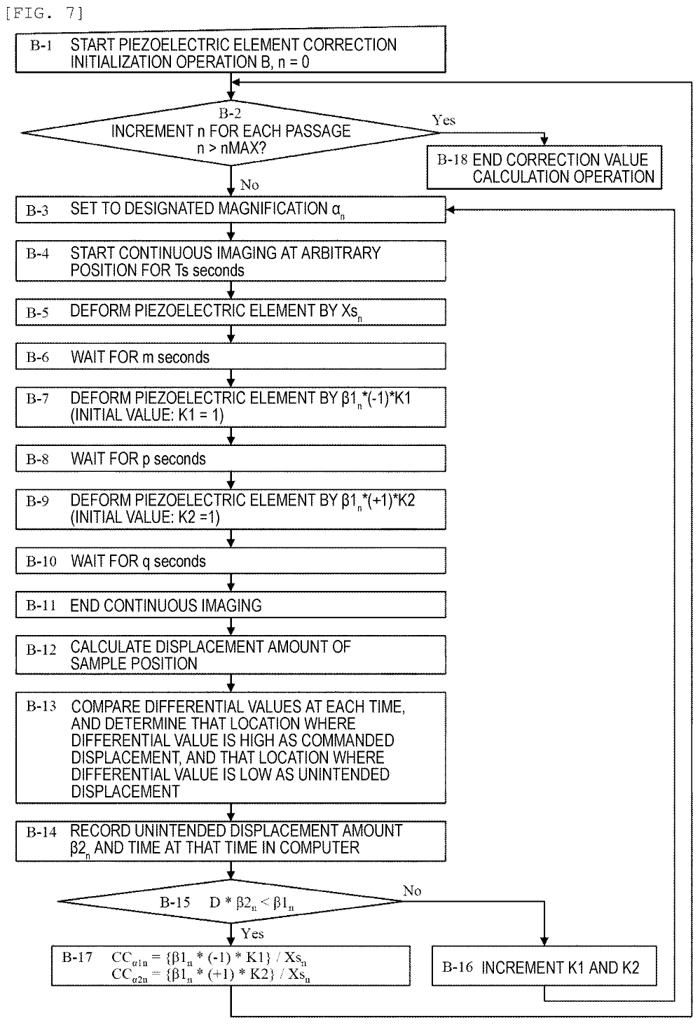

In the example of FIG. 4, Vₐᵢₘ 157=Vₐᵢₘ₂ 152, but when Vₐᵢₘ 157>Vₐᵢₘ₂ 152, the control voltage decreases from Vₐᵢₘ₂ 152 by V_{corr} 159 and further increases by a value greater than V_{corr} 159 to reach Vₐᵢₘ 157. The same applies to the example of FIG. 8, which will be described later.

As the operation principle, the fact that the larger the absolute displacement amount, the larger the creep displacement amount, and the smaller the absolute displacement amount, the smaller the creep displacement amount is utilized. A major commanded displacement Xₐᵢₘ₂ 153 is achieved by application of the Vₐᵢₘ₂ 152. After that, by decreasing the voltage by V_{corr} 159, the polarization generated in the piezoelectric element once is canceled or directed in the opposite direction. After that, when Vₐᵢₘ 157 is applied to return to the target displacement, the piezoelectric element is deformed again to the target deformation amount, and the polarization generated in the piezoelectric element is canceled, or becomes a polarization in the opposite direction.

At this time, since a voltage difference corresponding to V_{corr} 159 is smaller than the voltage difference from the initial value 0 to Vₐᵢₘ₂ 152, the creep displacement is also reduced, and as a result the creep displacement is suppressed.

A person skilled in the art can arbitrarily design a method for determining values related to correction (V_{corr} 159, t_{corr} 161, and the like). For example, a user may predict and determine a set value and store the set value in advance in the computer. The set value of the voltage can be, for example, a percentage (for example, several percent) of the voltage command value. The set value of the time can be, for example, several seconds.

Alternatively, it is also possible to measure the characteristics of the piezoelectric element in advance, determine a correction value, and record the correction value in the computer. In that case, it is possible to cope with changes in the characteristics of the piezoelectric element (due to temperature, humidity, usage history, and the like). The correction value may be automatically determined, for example, in the initialization operation of the scanning/transmission electron microscope 1. An example of a method for automatically determining the correction value is described below.

<Algorithm for Calculating Correction Value>

An example of a method for obtaining the correction value will be described below.

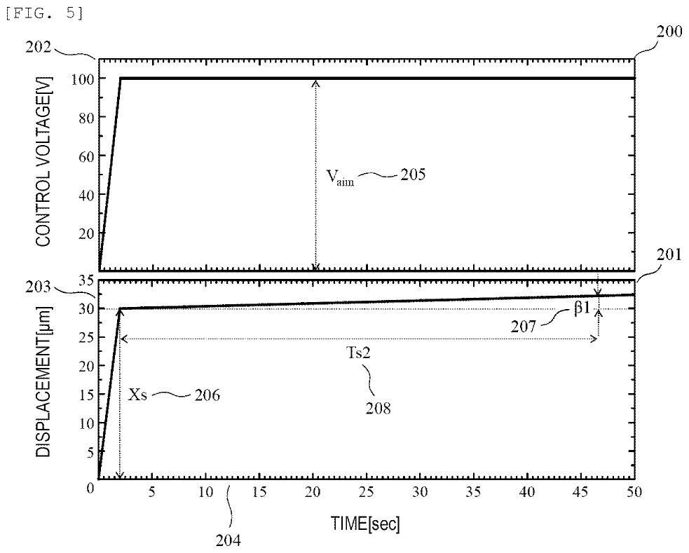

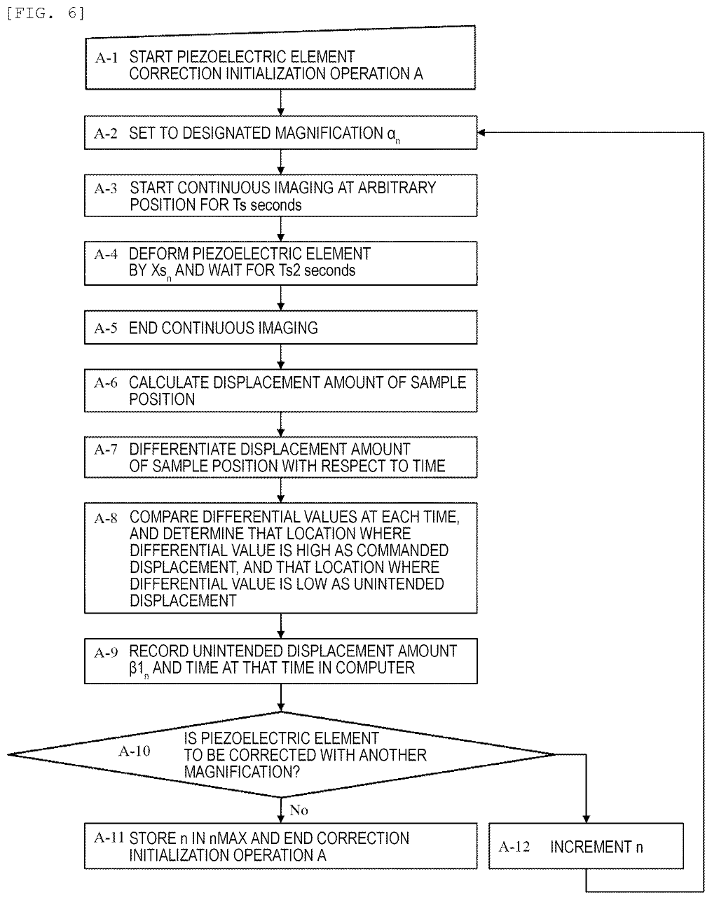

FIGS. 6 and 7 illustrate an algorithm for an operation (initialization operation) for obtaining the correction value. FIG. 6 particularly illustrates an algorithm for calculating the creep displacement when the piezoelectric element is deformed by a certain commanded amount. Each step will be described below.

Step A-1; The user presses an initialization operation start button. In response to this, or automatically at an appropriate time, the computer starts the piezoelectric element correction initialization operation A.

Step A-2; Magnification αₙ is designated. The magnification αₙ corresponds to magnification of a microscope image in the scanning/transmission electron microscope 1. The initial value of n is 1, and increases to the maximum value nMAX with the execution of a loop described below. For example, if the scanning/transmission electron microscope 1 can acquire microscopic images at three magnifications of 1,000, 2,000, and 4,000 times, the maximum value nMAX is 3, and α₁=1000, α₂=2000, and α₃=4000. The magnification αₙ may be input by the user, or automatically determined by the computer. The designated magnification αₙ is stored in the storage means.

Step A-3; In order to check the state of not being displaced, first, continuous imaging is started at an arbitrary position. This continuous imaging continues for Ts seconds until step A-5, which will be described later, is executed. An imaging interval of the continuous imaging is preferably shortened because the time resolution is improved when the imaging interval is shortened.

Instead of this continuous imaging, one or more images can be captured by raster scanning.

Step A-4: While continuing the continuous imaging started in step A-3, the piezoelectric element is deformed by Xsₙ (that is, the position of the sample is displaced by Xsₙ). After that, waiting is performed for Ts2 seconds to acquire the amount of creep displacement by the piezoelectric element. Xsₙ can be designated in advance. Xsₙ is preferably an amount smaller than the dimensions of the field of view. For example, Xsₙ is the dimension of the field of view multiplied by a predetermined constant K (where 0<K≤0.99).

Step A-5: The continuous imaging started in step A-3 is ended.

Step A-6; Based on a plurality of images obtained by continuous imaging or based on one or more images obtained by raster scanning, the displacement amount of the sample position (for example, the sample position in each image) due to the deformation of the piezoelectric element at each time is calculated.

Step A-7; The displacement amount by the piezoelectric element obtained in step A-6 is differentiated with respect to time. For example, the difference in displacement amount between two consecutive images can be acquired as a differential value.

Step A-8; It is judged whether the displacement at each time is due to the commanded displacement or creep displacement. For example, if the differential value of the displacement amount at a certain time is greater than a threshold value, it is judged that the displacement at that time is due to the commanded displacement, and otherwise, it is judged that the displacement at that time is due to the creep displacement. The threshold value may be designated in advance, or may be calculated based on the differential value of the displacement amount at each time, and the like.

Step A-9; A creep displacement amount β1ₙ (unintended displacement amount), which is the total displacement amount judged to be due to the creep displacement, the time when the creep displacement started, the time when the creep displacement ended, and the time from the start of the creep displacement to the end of the creep displacement are stored. In this way, the creep displacement amount β1ₙ is acquired as a drift amount of the field of view based on a plurality of charged particle beam images (based on one or more charged particle beam images when raster scanning is used).

Step A-10; It is judged whether or not another magnification αₙ by which the correction value should be determined exists. The judgement may be made manually by the user or automatically by the computer based on the maximum value of n designated in advance.

Step A-12; When it is judged in step A-10 that another magnification exists, n is incremented and the process returns to step A-2.

Step A-11; When it is judged in step A-10 that another magnification does not exist, n is stored in nMAX, and the correction initialization operation A is ended.

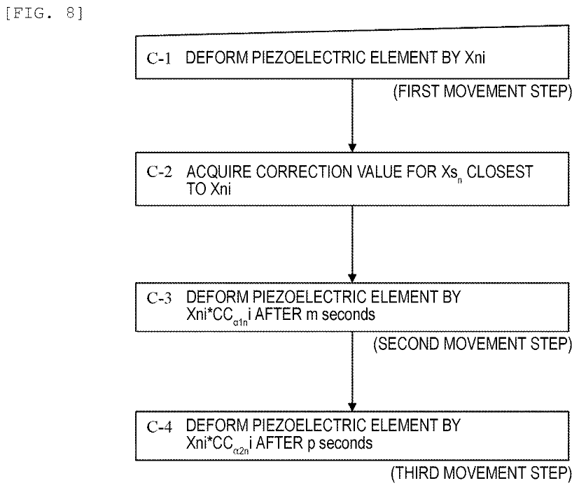

After execution of step A-11, the process of FIG. 7 may be executed, or the process of FIG. 9 may be executed.

FIG. 7 illustrates an algorithm especially for calculating a correction value used for the correcting operation, among the algorithms for the initialization operation for obtaining the correction value. Each step will be described below.

Step B-1: An initialization operation B for piezoelectric element correction is started. n is set to 0, that is, n=0.

Step B-2; n is incremented. If n>nMAX is satisfied, the process proceeds to step B-18. If n>nMAX is not satisfied, the process proceeds to step B-3.

Step B-3: Magnification an is designated. The magnification αₙ is common to step A-2.

Step B-4: In order to check the state of not being displaced, first, continuous imaging is started at an arbitrary position. This continuous imaging continues for Ts seconds until step B-11, which will be described later, is executed. An imaging interval of the continuous imaging is preferably shortened because the time resolution is improved when the imaging interval is shortened. Instead of this continuous imaging, one or more images can be captured by raster scanning.

Step B-5: While continuing the continuous imaging started in step B-4, the piezoelectric element is deformed by Xsₙ (that is, the position of the sample is displaced by Xsₙ).

Step B-6: Waiting is performed for m seconds to acquire a creep amount of the piezoelectric element.

Step B-7: While continuing the continuous imaging started in step B-4, the piezoelectric element is deformed by β1ₙ*(−1)*K1. Although K1 changes as described later, the initial value of K1 is set to 1.

Step B-8; Waiting is performed for p seconds.

Step B-9; While continuing the continuous imaging started in step B-4, the piezoelectric element is deformed by β1ₙ*(+1) *K2. Although K2 changes as described later, the initial value of K2 is set to 1.

Step B-10; Waiting is performed for q seconds.

Step B-11: The continuous imaging started in step B-4 is ended.

Step B-12; Based on a plurality of images obtained by continuous imaging or based on one or more images obtained by raster scanning, the displacement amount of the sample position (for example, the sample position in each image) due to the deformation of the piezoelectric element at each time is calculated.

Step B-13; The displacement amount by the piezoelectric element obtained in step B-12 is differentiated with respect to time. Further, in the same manner as in step A-8, it is judged whether the displacement at each time is due to the commanded displacement or due to the creep displacement.

Step B-14; A creep displacement amount β2ₙ (unintended displacement amount), which is the total displacement amount judged to be due to the creep displacement, the time when the creep displacement started, the time when the creep displacement ended, and the time from the start of the creep displacement to the end of the creep displacement are stored. In this way, the creep displacement amount β2ₙ is acquired as a drift amount of the field of view based on a plurality of charged particle beam images (based on one or more charged particle beam images when raster scanning is used).

Step B-15; It is judged whether or not the creep displacement has been suppressed. For example, when D*β2ₙ<β1ₙ, it is judged that the creep displacement has been suppressed, and otherwise, it is judged that the creep displacement has not been suppressed.

Here, D is a coefficient indicating how much the creep displacement should be suppressed, and is designated in advance. For example, in the case of D=5, when the creep displacement amount β2ₙ obtained by the process of FIG. 7 is ⅕ or less with respect to the creep displacement amount β1ₙ obtained by the process of FIG. 6, it is judged that the creep displacement has been suppressed.

When it is judged that the creep displacement has not been suppressed, the process proceeds to step B-16. When it is judged that the creep displacement has been suppressed, the process proceeds to step B-17.

Step B-16; After incrementing K1 and K2, the process proceeds to step B-3. As a modification, the initial values of K1 and K2 may be set to values greater than 1, and K1 and K2 may be decremented in step B-16.

Step B-17; A first correction value is set to CC_{α1n}={β1ₙ*(−1)*K1}/Xsₙ. A second correction value is set to CC_{α2n}={β1ₙ*(+1)*K2}/Xsₙ. In this way, the correction value is determined based on the drift amounts (β1ₙ and β2ₙ). This correction value corresponds to the movement amount in steps C-3 and C-4, which will be described later. In this example, both the first correction value and the second correction value are determined in this way, but only one of the correction values may be determined in this way, and the other may be determined by another method.

Thus, by determining the correction value based on actual imaging, the correction value becomes an appropriate value.

Further, each correction value is determined for each of a plurality of magnifications αₙ. Therefore, by appropriately setting the value of the constant K used in step A-4, correction values suitable for observation at various magnifications can be acquired.

Further, each correction value is determined for each of a plurality of target movement amounts. Therefore, by appropriately setting the value of the constant K used in step A-4, the correction values suitable for various target movement amounts can be acquired. For example, the target movement amount is Xsₙ, that is, it represents the movement amount when moving the sample from the current position to the target position.

After step B-17, the process proceeds to step B-2.

Step B-18; The correction value calculation process is ended. As a result of initialization operation, an array containing a set of {αₙ, β1ₙ, β2ₙ, Xsₙ, CC_{α1n}, CC_{α2n}} is output for each value of n.

FIG. 8 illustrates an algorithm of a piezoelectric element driving method with correction, in which correction is performed using the correction value obtained by the process of FIG. 7. This method is an example of a method for controlling the position of the sample in the charged particle beam device that moves the sample using the piezoelectric element.

Step C-1; The sample is moved toward the target position (first movement step). For example, the piezoelectric element is deformed by Xni. The value of Xni is determined based on a commanded displacement amount. Xni may be equal to a value of the commanded displacement amount. The commanded displacement amount may be input by the user using an interface such as a trackball, may be input by the user using a graphical user interface (GUI), or may be automatically calculated by the computer with respect to designated coordinates, or may be determined automatically by the computer by image recognition and the like.

Step C-2; The correction value is calculated. As a calculation method, first, the one closest to Xni (the one with the smallest absolute value of difference from Xni) is selected from among Xsₙ. Then, the correction values CC_{α1n} and CC_{α2n} corresponding to the selected Xsₙ are acquired and stored in CC_{αn}i and CC_{α2n}i.

Step C-3; After waiting for m seconds, the sample is moved away from the target position (second movement step). For example, the piezoelectric element is deformed by Xni*CC_{α1n}i.

Step C-4; After waiting for p seconds, the sample is moved toward the target position (third movement step). For example, the piezoelectric element is deformed by Xni*CC_{α2n}i.

Next, an example in which the process of FIG. 9 is executed instead of the process of FIG. 7 after the process of FIG. 6 will be described.

FIG. 9 illustrates an algorithm especially for calculating a correction value used for the correcting operation, among the algorithms for the initialization operation for obtaining the correction value. Each step will be described below.

Step D-1: An initialization operation D for piezoelectric element correction is started. n is set to 0, that is, n=0.

Step D-2; n is incremented. If n>nMAX is satisfied, the process proceeds to step D-15. If n>nMAX is not satisfied, the process proceeds to step D-3.

Step D-3: Magnification an is designated. The magnification αₙ is common to step A-2.

Step D-4: In order to check the state of not being displaced, first, continuous imaging is started at an arbitrary position. This continuous imaging continues for Ts seconds until step D-8, which will be described later, is executed. An imaging interval of the continuous imaging is preferably shortened because the time resolution is improved when the imaging interval is shortened. Instead of this continuous imaging, one or more images can be captured by raster scanning.

Step D-5: While continuing the continuous imaging started in step D-4, the piezoelectric element is deformed by Xsₙ (that is, the position of the sample is displaced by Xsₙ).

Step D-6: Waiting is performed for m seconds to acquire a creep amount of the piezoelectric element.

Step D-7: While continuing the continuous imaging started in step D-4, the piezoelectric element is displaced by β1ₙ*(−1)*K1. Although K1 changes as described later, the initial value of K1 is set to 1.

Step D-8; Waiting is performed for p seconds, and the continuous imaging is ended.

Step D-9; Based on a plurality of images obtained by continuous imaging or based on one or more images obtained by raster scanning, the displacement amount of the sample position due to the deformation of the piezoelectric element is calculated.

Step D-10; The displacement amount by the piezoelectric element obtained in step D-9 is differentiated with respect to time. Further, in the same manner as in step A-8, it is judged whether the displacement at each time is due to the commanded displacement or due to the creep displacement.

Step D-11; A creep displacement amount β2ₙ (unintended displacement amount), which is the total displacement amount judged to be due to the creep displacement, the time when the creep displacement started, the time when the creep displacement ended, and the time from the start of the creep displacement to the end of the creep displacement are stored. In this way, the creep displacement amount β2ₙ is acquired as a drift amount of the field of view based on a plurality of charged particle beam images (based on one or more charged particle beam images when raster scanning is used).

Step D-12; It is judged whether or not the creep displacement has been suppressed. For example, when D*β2ₙ<β1ₙ, it is judged that the creep displacement has been suppressed, and otherwise, it is judged that the creep displacement has not been suppressed.

When it is judged that the creep displacement has not been suppressed, the process proceeds to step D-14. When it is judged that the creep displacement has been suppressed, the process proceeds to step D-13.

Step D-14; After incrementing K1, the process proceeds to step D-3. As a modification, the initial value of K1 may be set to a value greater than 1, and K1 may be decremented in step D-14.

Step D-13; The correction value is set to CC_{αn}={β1ₙ*(−1)*K1}/Xsₙ. In this way, the correction value is determined based on β1ₙ, that is, the drift amount. After that, the process proceeds to step D-2.

Step D-15; The correction value calculation process is ended. As a result of the initialization operation, an array containing a set of {αₙ, β1ₙ, β2ₙ, Xsₙ, CC_{αn}} is output for each value of n.

FIG. 10 illustrates an algorithm of a piezoelectric element driving method with correction, in which correction is performed using the correction value obtained by the process of FIG. 9. This method is an example of a method for controlling the position of the sample in the charged particle beam device that moves the sample using the piezoelectric element.

Step E-1; The sample is moved beyond the target position (fourth movement step). For example, in the same manner as in step C-1, the piezoelectric element is deformed by Xni. However, Xni is a displacement amount larger than the target displacement amount.

Xni can be, for example, a value obtained by adding a correction value to the target displacement amount. In that case, step E-2 may be executed prior to step E-1.

Step E-2; The correction value is calculated. As a calculation method, first, the one closest to Xni (the one with the smallest absolute value of difference from Xni) is selected from among Xsₙ. Then, the correction value CC_{αn} corresponding to the selected Xsₙ is acquired and stored in CC_{αn}i.

Step E-3; After waiting for m seconds, the sample is moved toward the target position (fifth movement step). For example, the piezoelectric element is deformed by Xni*CC_{αn}i.

<Description on UI when Calculating Correction Value>

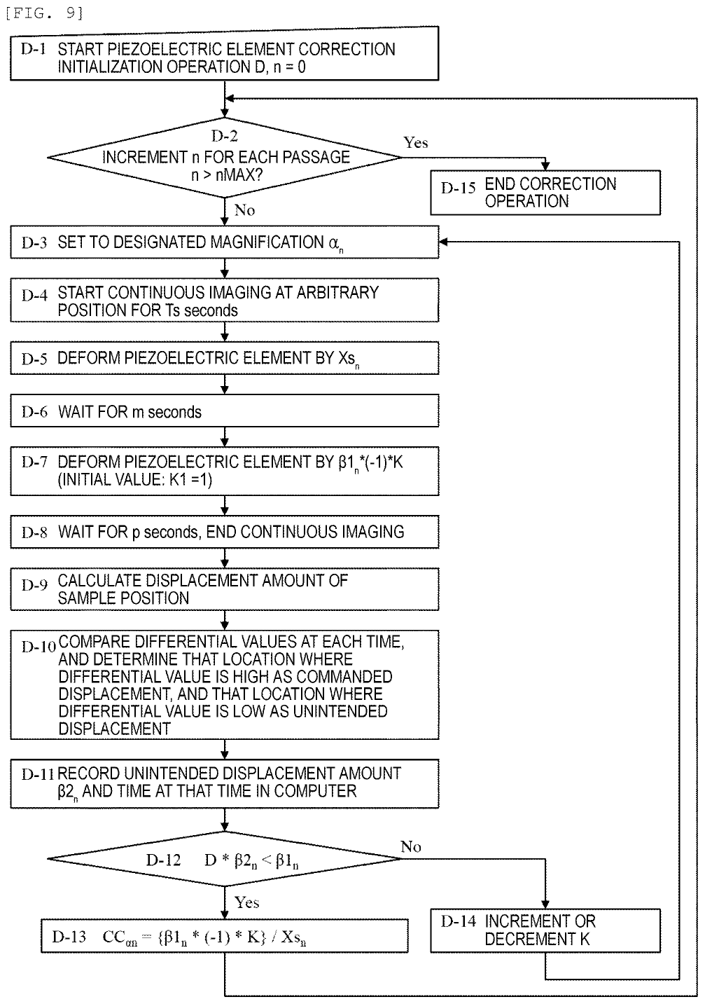

FIGS. 11, 12, and 13 illustrate examples of the user interface (UI) according to the first example. This UI is used when calculating the correction value for piezoelectric element correcting operation. This UI particularly displays whether or not the charged particle beam image is suitable for determining the correction value for each of the X-, Y- and Z-directions.

The UI displays a charged particle beam image display screen 301 that displays a charged particle beam image, and a window 304 that indicates whether or not the charged particle beam image is appropriate. The window 304 includes an indicator 302 and a button 303.

The indicator 302 is provided for each piezoelectric element and displays whether or not the correction value calculation operation can be performed for the piezoelectric element based on the charged particle beam image. The button 303 is a button that the user presses when starting the correction value calculation operation. The scanning/transmission electron microscope 1 starts the correction value calculation operation (for example, the processes in FIGS. 6 and 7) in response to pressing the button 303.

As an example of the relationship between the indicator 302 and the button 303, the button 303 can be pressed only when the indicator 302 is performing a predetermined display operation (lighting, blinking, and the like). However, the indicator 302 may be configured to be able to be pressed, and the button 303 may be configured to perform a predetermined display operation.

As an example of the relationship between the charged particle beam image display screen 301, the indicator 302, and the button 303, when the charged particle beam image is suitable for determining the correction value in the X-direction, the indicator 302 corresponding to the X-direction performs a predetermined display operation and the button 303 corresponding to the X-direction can be pressed. The same applies to the Y-direction. Although the same configuration can be adopted for the Z-direction, when it is not possible to determine whether or not the correction value can be calculated in the Z-direction only from the charged particle beam image, the Z-direction may be determined in other ways, or the display for the Z-direction may be omitted.

Here, whether or not the charged particle beam image is suitable for determining the correction value in a certain direction can be determined, for example, based on a component in the corresponding direction in the charged particle beam image.

In the example of FIG. 11, both the X-direction component and the Y-direction component exist in the charged particle beam image. That is, since sufficient contrast can be obtained for both the X-direction component and the Y-direction component, the charged particle beam image is suitable for calculating the correction value in both the X- and Y-directions.

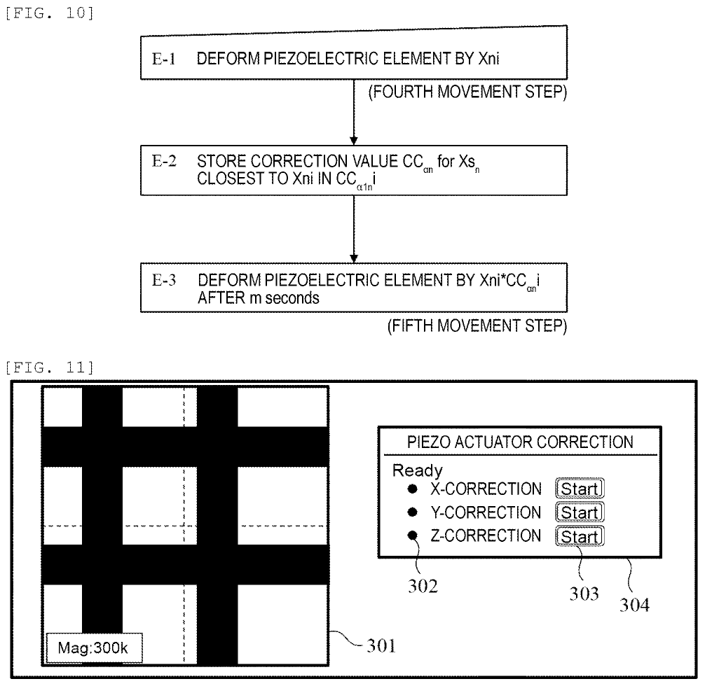

In the example of FIG. 12, the X-direction component is insufficient in the charged particle beam image, and sufficient contrast cannot be acquired. On the other hand, the Y-direction component exists in the charged particle beam image, and sufficient contrast can be acquired. Therefore, the charged particle beam image is not suitable for calculating the correction value in the X-direction, but is suitable for calculating the correction value in the Y-direction.

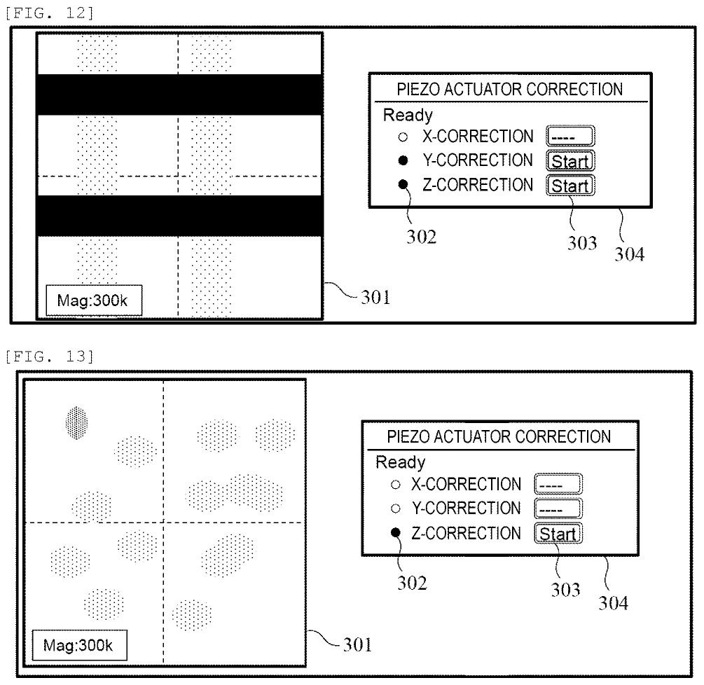

In the example of FIG. 13, both the X-direction component and the Y-direction component are insufficient in the charged particle beam image. Sufficient contrast cannot be acquired for both the X-direction component and the Y-direction component, and the charged particle beam image is not suitable for calculating the correction value for either the X-direction or the Y-direction.

In this way, whether or not the charged particle beam image is suitable for determining the correction value is displayed, and thus the user can start a correction value determination operation based on the appropriate charged particle beam image.

In the examples of FIGS. 11, 12, and 13, whether or not there is strong bar-shaped contrast in the X-direction and whether or not there is strong bar-shaped contrast in the Y-direction is used as a criterion for deciding the suitability of the correction value calculation operation for each direction. A person skilled in the art can appropriately design specific calculation formulas, thresholds, and the like used for decision. Further, the decision criteria are not limited to those described with reference to FIGS. 11 to 13.

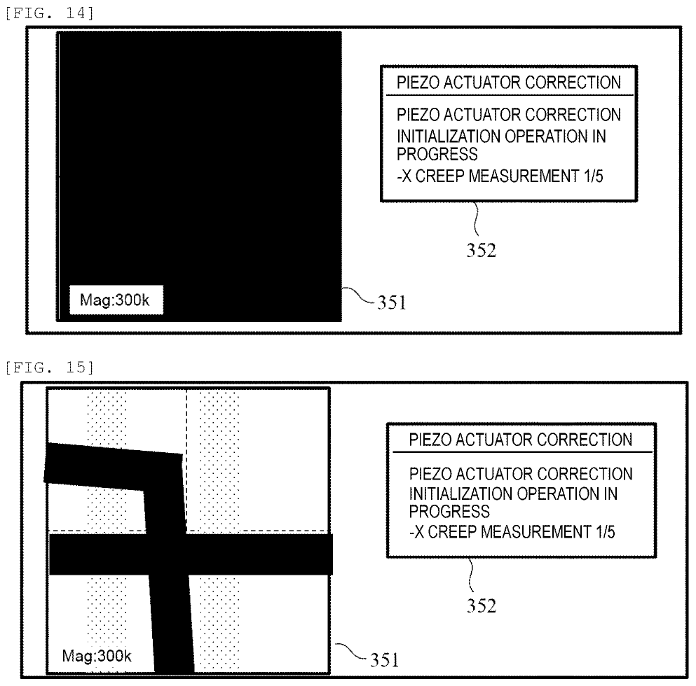

FIGS. 14 and 15 illustrate another example of the UI according to the first example. This UI is used when calculating the correction value for the piezoelectric element correcting operation. This UI displays whether or not acquisition of the drift amount is being executed.

The UI displays a charged particle beam image display part 351 and an indicator part 352 that displays what kind of processing is currently being performed.

In the example of FIG. 14, both the charged particle beam image display part 351 and the indicator part 352 display that the initialization operation (including the drift amount acquisition operation) is being executed. The charged particle beam image is not displayed (that is, the entire charged particle beam image display part 351 is black) during initialization operation. Further, the indicator part 352 displays a message “initialization operation in progress”.

In the example of FIG. 14, the screen is black as one mode of non-display, but the mode of non-display is not limited thereto. For example, the entire charged particle beam image display part 351 may be displayed in white, a charged particle beam image immediately before the start of the initialization operation may be displayed, or another image may be displayed.

In the example of FIG. 15, the charged particle beam image display part 351 displays the current charged particle beam image, and only the indicator part 352 displays that the initialization operation (including drift amount acquisition operation) is being executed.

Thus, by displaying whether or not the initialization operation is being executed, the user can easily grasp the state of the scanning/transmission electron microscope 1, and the user's convenience is improved.

### REFERENCE SIGNS LIST

1: scanning/transmission electron microscope (charged particle beam device)
2: control device
3: stage
4: electron gun
5: electron optical system
6: imaging system
7: electron source
8: suppression electrode
9: extraction electrode
10: anode
11: focusing lens
12: deflection lens
13: objective lens
14: stage drive mechanism
15: stage rod
16: sample holder
18: fluorescent plate
19: detector
20: camera
22: primary electrons
23: signal electron
24: transmitted electrons
25: fluorescence
33: computer
33A: CPU
33B: image processing unit
33C: display device
33D: memory
34: main control unit
35: stage control unit
35A: stage motion computation unit
35B: motor driver
35C: piezoelectric driver
36: signal processing unit
50: electron microscope main body
52: X-actuator
53: Y-actuator
54: X-piezoelectric element
55: Y-piezoelectric element
57: movement direction Xₓ
58: movement direction X_{y}
59: sample
60: stage rod insertion mechanism
64: Z-actuator
65: Z-piezoelectric element
66: movement direction X_{z}
150: voltage-time graph
151: displacement-time graph
152: Vₐᵢₘ₂
153: Xₐᵢₘ₂
154: control voltage axis
155: displacement axis
156: time axis
157: Vₐᵢₘ
158: Xₐᵢₘ
159: V_{corr}
160: X_{corr}
161: t_{corr}
200: voltage-time graph
201: displacement-time graph
202: control voltage axis
203: displacement axis
204: time axis
205: Vₐᵢₘ
206: Xs
207: β1
208 Ts
301: charged particle beam image display screen
302: indicator
303: button
304: window
351: charged particle beam image display part
352: indicator part

1.-11. (canceled)

12. A method for controlling a position of a sample in a charged particle beam device that moves the sample using a piezoelectric element, the method comprising:
a first movement step of moving the sample toward a target position;
a second movement step of moving the sample away from the target position, after the first movement step; and
a third movement step of moving the sample toward the target position, after the second movement step.

13. A method for controlling a position of a sample in a charged particle beam device that moves the sample using a piezoelectric element, the method comprising:
a first movement step of moving the sample toward a target position;
a second movement step of moving the sample away from the target position, after the first movement step;
a third movement step of moving the sample toward the target position, after the second movement step;
a step of acquiring a drift amount of a field of view based on one or more charged particle beam images; and
a step of determining a movement amount in at least one of the second movement step and the third movement step as a correction value based on the drift amount.

14. The method according to claim 13, wherein
the correction value is determined for a plurality of magnifications relating to the charged particle beam image.

15. The method according to claim 13, wherein
the correction value is determined for a plurality of target movement amounts.

16. The method according to claim 13, wherein the method comprises
a step of displaying whether or not the charged particle beam image is suitable for determining the correction value.

17. The method according to claim 13, wherein the method comprises
a step of displaying whether or not acquisition of the drift amount is being executed.

18. A method for controlling a position of a sample in a charged particle beam device that moves the sample using a piezoelectric element, the method comprising:
a first movement step of moving the sample toward a target position;
a second movement step of moving the sample away from the target position, after the first movement step; and
a third movement step of moving the sample toward the target position, after the second movement step, or comprising:
a fourth movement step of moving the sample beyond the target position; and
a fifth movement step of moving the sample toward the target position, after the fourth movement step,
wherein the method further comprises:
a step of acquiring a drift amount of a field of view based on one or more charged particle beam images; and
a step of determining a movement amount in at least one of the second movement step, the third movement step, and the fifth movement step, based on the drift amount.

19. A program that causes a charged particle beam device to execute the method according to claim 12.

20. A storage medium that stores the program according to claim 19.

21. A control device of a charged particle beam device, the control device executing the method according to claim 12.

22. A charged particle beam device comprising:
a sample holder on which a sample is placed;
a piezoelectric element that is connected to the sample holder and moves the sample; and
the control device according to claim 21.
